(19) United States
(12) Patent Application Publication
(10) Pub. No.: US 2025/0375815 A1
(43) Pub. Date: Dec. 11, 2025

(54) METHOD FOR MANUFACTURING THREE-DIMENSIONAL STRUCTURE USING CONDUCTIVE FLOATING MASK

(71) Applicants: GLOBAL FRONTIER CENTER FOR MULTISCALE ENERGY SYSTEMS, Seoul (KR); SEOUL NATIONAL UNIVERSITY R&DB FOUNDATION, Seoul (KR)

(72) Inventors: Mansoo CHOI, Seoul (KR); Peter V. PIKHITSA, Seoul (KR); Yoon-ho JUNG, Seoul (KR); Jooyeon SHIN, Seoul (KR); Wooik JUNG, Gyeonggi-do (KR); Changnyeong HUR, Seoul (KR); Wonjin CHO, Seoul (KR)

(21) Appl. No.: 18/730,160

(22) PCT Filed: Sep. 19, 2022
(86) PCT No.: PCT/KR2022/013955

§ 371 Date: Feb. 3, 2025

(30) Foreign Application Priority Data
Jan. 24, 2022 (KR) 10-2022-0010066

(51) Int. Cl. B22F 10/25; B22F 10/30; B22F 12/33; B33Y 10/00; B33Y 30/00; B33Y 80/00; B82B 3/00

(52) U.S. Cl. CPC B22F 10/25; B22F 10/30; B22F 12/33; B22F 2202/06; B33Y 10/00; B33Y 30/00; B33Y 80/00; B82B 3/0076

(57) ABSTRACT

The present invention may be configured to: apply, while maintaining a separation distance (d) between a substrate and a conductive mask, different electric potentials to each of the substrate and the mask to form an electric field due to an electric potential difference; to make charged nanoparticles pass through a hole of the mask according to the intensity of the electric field to determine the degree to which the charged nanoparticles are focused on the substrate; and control the size and shape of a three-dimensional structure formed by depositing the nanoparticles on the substrate according to the focusing degree.

### TECHNICAL FIELD

The present application claims the benefit of priority based on Korean Patent Application No. 10-2022-0010066 filed on Jan. 24, 2022, the entire disclosure of which is incorporated as a part of this specification.

The present disclosure relates to a method of manufacturing a three-dimensional structure with controlled size and shape by adjusting an electric field between a conductive floating mask and a substrate to focus charged nanoparticles.

### BACKGROUND ART

Three-dimensional nanoprinting is a technology for producing micro- to nano-sized three-dimensional structures by selectively controlling charged nanoparticles, focusing and depositing them at a desired location, and is attracting attention as a next-generation smart manufacturing process in the aerospace industry, home appliances, and consumer goods industries.

The three-dimensional structure is affected by the purity, composition, shape, and size of the components, and has a limitation in that existing nanoprinting technology using ink has low purity of components, requires special environments such as vacuum, and can only produce one structure at a time.

An ion-assisted three-dimensional nanoprinting technology developed to overcome these limitations has the advantage of being a dry process, which does not contain impurities such as ink, so the purity of the structure is high, and it is economically efficient as thousands of nanostructures can be produced at a time at room temperature and pressure.

The ion-assisted nanoprinting process is carried out in a deposition chamber containing a non-conductive floating mask and a conductive substrate. The non-conductive floating mask is formed of a non-conductive material and has thousands or more patterns to focus charged nanoparticles. For example, when a negative electric potential is applied to a conductive substrate and positive ions and positively charged nanoparticles are injected into the deposition chamber, the low-mass positive ions first accumulate on the surface of the non-conductive floating mask due to an electric field within the chamber, and when the positive ions accumulated on the mask surface distort the electric field around the pattern into a lens shape, the positively charged nanoparticles are focused along the distorted electrostatic lens, and three-dimensional structures of various shapes can be produced through a three-dimensional nanostage.

However, in this ion-assisted three-dimensional nanoprinting, it is difficult to adjust the amount of ions accumulated in the non-conductive mask, which is important for forming electrostatic lenses, making it difficult to precisely control the size of the nanostructure.

Therefore, in three-dimensional nanoprinting, a technology is needed that can induce a uniform shape by efficiently controlling the size of a finally obtained structure.

### DISCLOSURE OF THE INVENTION

### Technical Goals

In order to solve the above problems, the present disclosure provides a method of inducing changes in the size and shape of a finally obtained three-dimensional structure by adjusting the electric field between the mask and the substrate, which replaces the role of ions in the three-dimensional nanoprinting process.

### Technical Solutions

According to an aspect of the present disclosure, there is provided a method of manufacturing a three-dimensional structure including:
(S1) a step of disposing a lower substrate and a conductive mask provided with a plurality of holes above the lower substrate to be spaced apart within a grounded reactor;
(S2) a step of forming an electrostatic lens around the hole of the mask by generating electric fields of different sizes in the conductive mask and the lower substrate, respectively;
(S3) a step of introducing charged nanoparticles through an upper inlet of the reactor to induce passage through the mask hole by the electrostatic lens and deposition on the lower substrate; and
one or more steps of the following steps (S4) and (S5):
(S4) a step of adjusting an electric field intensity between the conductive mask and the substrate to induce a change in size of a structure; and
(S5) a step of controlling a shape of a growing three-dimensional nanostructure while transporting the lower substrate in three dimensions is provided.

According to another aspect of the present disclosure,
there is provided an apparatus for manufacturing a three-dimensional structure for use in the method above, including,
a grounded reactor,
a lower substrate located within the grounded reactor,
a conductive mask disposed to be spaced apart above the lower substrate and provided with a plurality of holes,
an electric field applying means for generating electric fields of different sizes in the conductive mask and the lower substrate, respectively, to form an electrostatic lens around the hole of the mask;
a nanoparticle introducing means for introducing charged nanoparticles into an upper part of the conductive mask;
an electric field adjusting means for adjusting the size of the electric field applied to the conductive mask and the lower substrate; and
a transporting means for transporting the lower substrate in three dimensions is provided.

### Advantageous Effects

According to the present disclosure, when manufacturing a three-dimensional structure, different electric fields are formed on each of a substrate and a conductive mask, and it is possible to determine the degree to which charged nanoparticles pass through holes of the mask and are focused on the substrate depending on the intensity of the electric field, and to control the size and shape of the three-dimensional structure formed by depositing nanoparticles on the substrate according to the degree of concentration while transporting the lower substrate in three dimensions.

### BRIEF DESCRIPTION OF DRAWINGS

FIG. 1 schematically illustrates a process of manufacturing a three-dimensional structure inside a reactor according to an embodiment of the present disclosure.

FIGS. 2 to 5 are SEM images showing changes in height, thickness, and shape of a structure according to an electric field intensity between a substrate and a mask in an example.

FIG. 6 is an SEM image showing controlling a shape of a three-dimensional nanostructure growing while transporting a lower substrate in three dimensions in an example.

FIGS. 7 and 8 are graphs showing changes in size of a structure according to an electric field intensity between a substrate and a mask in an example.

### BEST MODE FOR CARRYING OUT THE INVENTION

Since the present disclosure can be modified in various ways and can have various embodiments, specific embodiments will be illustrated in the drawings and described in detail in the detailed description. However, this is not intended to limit the present disclosure to specific embodiments, and should be understood to include all modifications, equivalents, and substitutes included in the spirit and technical scope of the present disclosure. In describing the present disclosure, when it is determined that a detailed description of related known technologies may obscure the gist of the present disclosure, the detailed description will be omitted.

An embodiment of the present disclosure relates to a method of manufacturing a three-dimensional structure with controlled size and shape through electric field adjustment using a distance between a mask and a substrate, a potential difference, or a size of a hole of the mask.

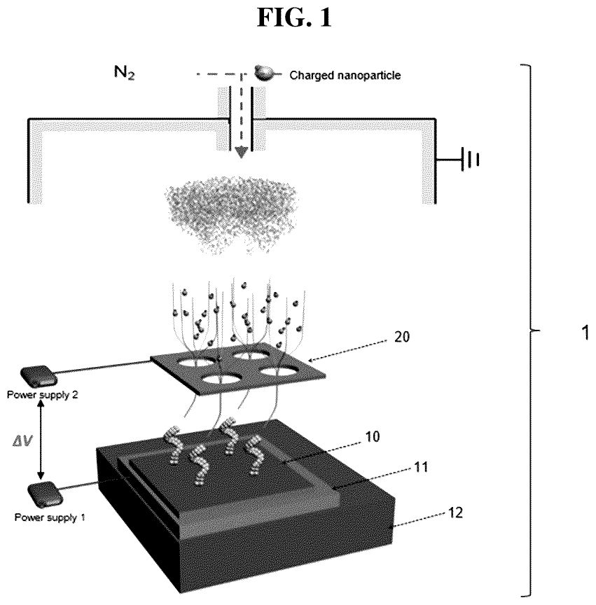

FIG. 1 schematically illustrates a process of manufacturing a three-dimensional structure inside a reactor according to an embodiment of the present disclosure, and hereinafter, the method of manufacturing a three-dimensional structure according to the present disclosure will be described in detail with reference to FIG. 1.

Referring to FIG. 1, in the present disclosure, a three-dimensional structure may be manufactured in a reactor (a deposition chamber) 1 whose body is grounded and which includes a lower substrate 10 and a conductive floating mask 20 therein.

The lower substrate 10 may be a substrate commonly used in nanopatterning, such as a substrate made of a conductive material such as silicon (Si), indium tin oxide (ITO), or silicon carbide (SiC), or a type in which layers of conductive and non-conductive materials exist simultaneously in one substrate, and an electric potential may be applied by placing the substrate on an electrode layer 11 and connecting a power source. Additionally, the lower substrate 10 may be combined with a three-dimensional nanostage 12 to control a growth direction of deposited nanoparticles.

The conductive mask 20 includes a form in which a single hole serving as a nozzle is present in a film coated with a thin metal film, a form in which a plurality of holes are provided in a pattern, or a form in which a plurality of holes are provided as a metal mesh, and may apply electric potentials of different magnitudes to the plurality of holes to individually control the electric fields of the plurality of nozzles. The conductive mask 20 may be disposed at a predetermined distance (d) apart from the lower substrate 10. The thin metal film or metal mesh may include chromium (Cr), gold (Au), or mixtures thereof, but is not limited thereto.

While maintaining the separation distance (d) between the lower substrate 10 and the conductive mask 20, electric potentials of different magnitudes may be applied to the substrate and the mask, respectively, to generate an electric field, and an electrostatic lens may be uniformly formed around the hole of the mask by the electric field. In addition, on the contrary, the intensity of the electric field may be adjusted by adjusting the separation distance while the electric field is applied or by changing the size of the hole provided in the mask.

With the electrostatic lens formed, when charged nanoparticles are introduced together with a carrier gas (e.g., nitrogen, helium, or argon) through an upper inlet of the reactor, the charged nanoparticles are focused as they pass through the hole of the conductive mask 20 by the electrostatic lens and deposited on the lower substrate 10 to grow a structure of nanoparticles. At this time, according to the intensity of the electric field between the conductive mask and the substrate, the degree to which the nanoparticles pass through the hole of the mask and are focused on the substrate, i.e., the width of the structure, may be determined.

Therefore, by adjusting the separation distance (d) between the conductive mask and the substrate, the magnitude of the electric potential applied thereto, or the intensity of the electric field generated using the hole size of the mask, the size, shape, and even arrangement of a finally obtained three-dimensional structure may be precisely controlled.

The hole diameter of the mask may range, for example, from 500 nm to 10 μm, and specifically, may be 1 μm or more, 2 μm or more, 3 μm or more, 4 μm or more, and 9 μm or less, 8 μm or less, 7 μm or less, and 6 μm or less, but is not limited thereto.

Further, various forms of three-dimensional structures may be manufactured by controlling the growth direction, height, and width of the nanoparticles deposited on the substrate through the movement of the three-dimensional nanostage 12 coupled under the lower substrate 10. In addition, since this method is a dry process that does not use ink, it is advantageous in terms of processability because it does not contain impurities such as polymers.

The charged nanoparticles may be particles with a size of 1 to 10 nm produced by spark discharging a precursor, and the precursor may be a conductive material selected from palladium, gold, copper, tin, indium, ITO, graphite, and silver; a conductive material coated with an insulating material selected from cadmium oxide, iron oxide, and tin oxide; or a semiconductor material selected from silicon, GaAs, and CdSe. Alternatively, any charged nanoparticles made through evaporation & condensation, electrospray ionization, etc., may be applied to the present technology.

In an embodiment of the present disclosure, the separation distance (d) between the conductive mask and the substrate may be 0.5 to 20 μm, specifically 1.1 to 11 μm, and the difference between electric potentials (ΔV) applied to the conductive mask and the substrate may be 50 to 300 V, specifically 75 to 200 V.

In an embodiment of the present disclosure, the electric field intensity between the conductive mask and the substrate may be 5 V/μm to 200 V/μm, for example, 16.67 V/μm to 100 V/μm.

For example, when applying different electric potentials of −1400 V to the mask and −1500 V to the substrate while maintaining the separation distance (d) between the conductive mask and the substrate at 2 to 4 μm, an electric field of 25 to 75 V/μm may be generated between the mask and the substrate.

In the present disclosure, as shown in Equation 1 below, the intensity of the electric field generated using the separation distance (d) between the conductive mask and the substrate and the magnitude of each applied electric potential may be expressed as the magnitude of the electric potential applied to the substrate relative to the moving distance of the charged nanoparticles, i.e., the distance between the upper inlet of the reactor and the substrate, which means the electric field intensity formed in the entire area of the reactor.

Eₙₒₘ=electric potential of substrate (V)/Moving distance of charged nanoparticles (μm) [Equation 1]

In addition, as described above, in the present disclosure, since the degree to which the nanoparticles pass through the hole of the mask and are focused on the substrate (i.e., the width size of the structure) may be determined according to the intensity of the electric field between the conductive mask and the substrate, from their correlation, the size of the finally obtained three-dimensional structure may be predicted.

For example, a three-dimensional structure manufactured by the method of the present disclosure may have a size that satisfies Equation 2 below.

$${W}_{D} = {W ( \frac{α {E}_{nom} d}{Δ V} )}^{\frac{1}{2}} ( \frac{2}{\sqrt{π}} ) \qquad [ Equation 2 ]$$

In the above equation,
W_{D} is a diameter (μm) of a stump of the three-dimensional structure,
W is a spacing (μm) between the holes provided in the conductive mask,
ΔV is an electric potential difference (V) between the conductive mask and the lower substrate,
d is a separation distance (μm) between the conductive mask and the lower substrate,
α is a constant, and
Eₙₒₘ is an intensity of the electric field (V/μm) generated by the electric potential difference between the conductive mask and the lower substrate.

The α is a factor to compensate for the electric field intensity that changes due to geometrical elements of the area where the charged nanoparticles enter from the top of the mask, and may have a value of 5, for example.

The Equation 2 above may be useful for predicting and controlling the size and shape of the finally obtained three-dimensional structure through the electric potential difference and separation distance between the substrate and the mask applied during the manufacturing process of the three-dimensional structure, and the intensity of the electric field generated therefrom.

### MODES FOR CARRYING OUT THE INVENTION

Hereinafter, examples will be described in detail to help understanding of the present disclosure. However, the examples according to the present disclosure may be modified into various other forms, and the scope of the present disclosure should not be construed as being limited to the following examples. Examples of the present disclosure are provided to more completely explain the present disclosure to those skilled in the art.

### Example 1

As shown in FIG. 1, the lower silicon substrate 10 was placed on the electrode layer 11 in the grounded reactor 1 and combined with the piezo nanostage 12. A Cr/Au coating film was placed to be spaced apart from the silicon substrate as the conductive floating mask 20 provided with a plurality of holes (4 μm in diameter). While applying an electric potential of −1500 V to the substrate, and applying an electric potential varying from −1425 V, −1400 V, −1350 V and −1300 V to the surface of the mask, charged nanoparticles of 5 nm or less obtained by spark discharge were introduced through the upper inlet of the reactor to manufacture a three-dimensional structure in which nanoparticles were grown on the lower substrate 10. Various conditions were applied to change the separation distance between the mask and the substrate and to change a moving speed and direction of the piezo nanostage 12.

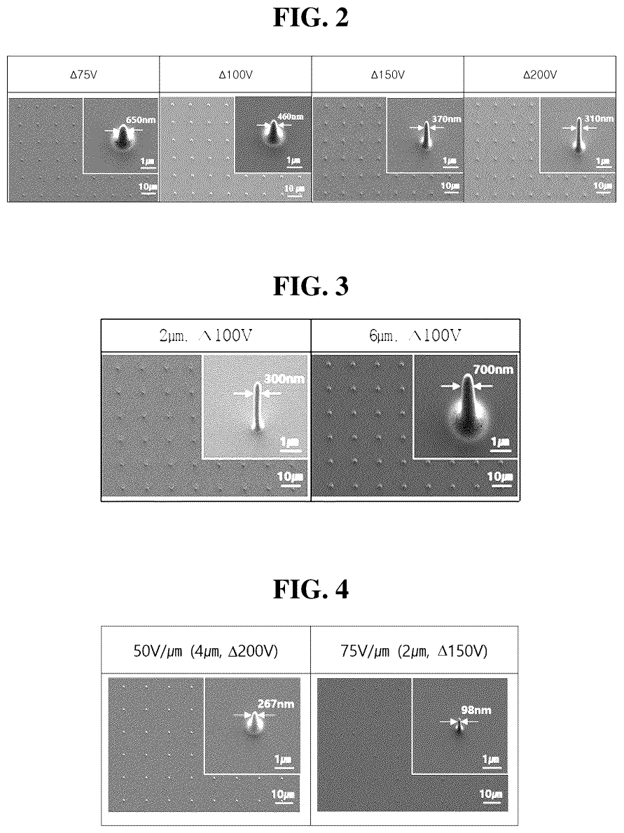

FIGS. 2 to 6 are SEM images showing changes in height, thickness, and shape of a structure according to an electric field intensity between a substrate and a mask applied in the example.

In FIG. 2, it can be seen that, when the separation distance between the conductive mask and the substrate is 4 μm, the width of the three-dimensional structure is controlled from 650 nm to 310 nm by the potential difference (ΔV) of 75 V, 100 V, 150 V, and 200 V.

In FIG. 3, it can be seen that, when the separation distance is changed to 2 μm and 6 μm under the condition that the potential difference between the conductive mask and the substrate is 100 V, the width of the three-dimensional structure is controlled from 300 nm to 700 nm.

FIG. 4(a) shows the results of an experiment with a conductive mask hole size of 2 μm, a separation distance of 4 μm, and a potential difference of 200 V, confirming that the thickness of the structure was controlled from 310 nm to 267 nm, and FIG. 4(b) shows the result confirming that the thickness of the structure is controlled to 98 nm with a hole size of 2 μm, a separation distance of 2 μm, and a potential difference of 150V. From the results in FIG. 4, it can be seen that even when the hole size is changed, the thickness of the structure is controlled by adjusting the electric field intensity (from 50 V/μm to 75 V/μm).

FIG. 5 illustrates that structures with various thicknesses were produced in a single process on the same substrate, FIG. 5(a) illustrates a structure with a thickness change by applying a different potential difference during the process, FIG. 5(b) illustrates another structure with a thickness change by applying a different potential difference during the process, and FIG. 5(c) illustrates an array formed by moving the piezo nanostage 12 into the space between the structures and changing the electric field to manufacture secondary structures with different thicknesses on the same substrate.

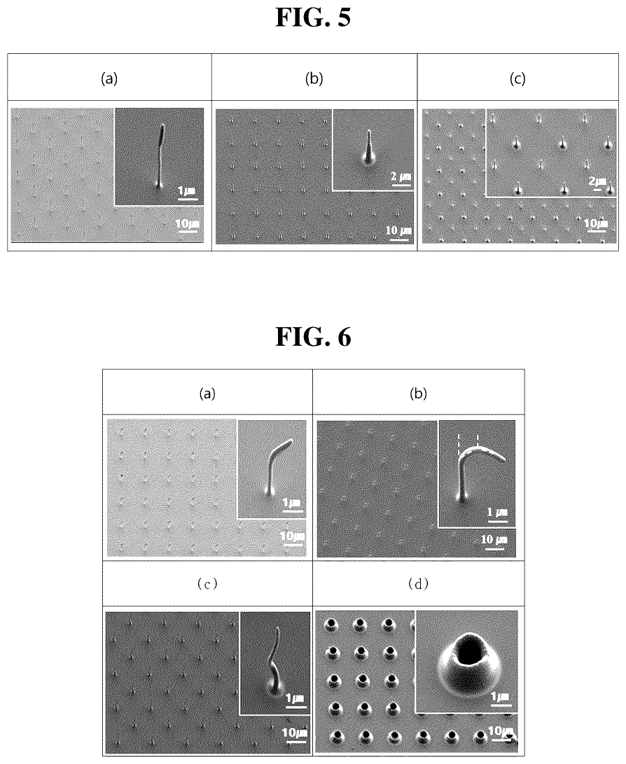

In FIG. 6, as a result of changing the moving speed and direction of the piezo nanostage 12 while controlling the electric field intensity between the conductive mask and the substrate, it can be seen that three-dimensional structures are manufactured in various shapes such as (a) a slanted structure, (b) a downward structure, (c) a helix structure, and (d) a wall structure.

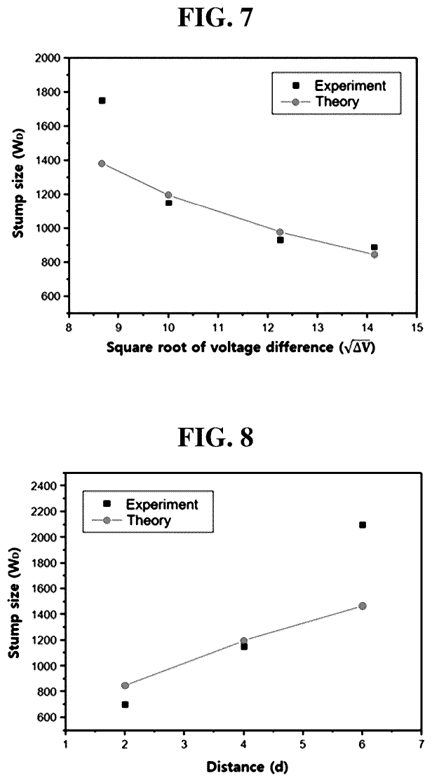

FIGS. 7 and 8 are graphs showing changes in size of a structure according to an electric field intensity between a substrate and a mask applied in an example, and the correlation between respective factors was derived from these graphs to define Equation 2 below.

$${W}_{D} = {W ( \frac{α {E}_{nom} d}{Δ V} )}^{\frac{1}{2}} ( \frac{2}{\sqrt{π}} ) \qquad [ Equation 2 ]$$

In the above equation,

In the above equation,
W_{D} is a diameter (μm) of a stump of the three-dimensional structure,
W is the spacing (μm) between the holes provided in the conductive mask,
ΔV is the electric potential difference (V) between the conductive mask and the lower substrate,
d is the separation distance (μm) between the conductive mask and the lower substrate,
α is a constant, such as 5, and
Eₙₒₘ is the intensity of the electric field (V/μm) generated by the electric potential difference between the conductive mask and the lower substrate.

The Equation 2 above may be useful for predicting and controlling the size and shape of the finally obtained three-dimensional structure through the electric potential difference and separation distance between the substrate and the mask applied during the manufacturing process of the three-dimensional structure, the intensity of the electric field generated therefrom, and the like.

1. A method of manufacturing a three-dimensional structure, the method comprising:
(S1) a step of disposing a lower substrate and a conductive mask provided with a plurality of holes above the lower substrate to be spaced apart within a grounded reactor;
(S2) a step of forming an electrostatic lens around the hole of the mask by generating electric fields of different sizes in the conductive mask and the lower substrate, respectively;
(S3) a step of introducing charged nanoparticles through an upper inlet of the reactor to induce passage through the mask hole by the electrostatic lens and deposition on the lower substrate; and
one or more steps of the following steps (S4) and (S5):
(S4) a step of adjusting an electric field intensity between the conductive mask and the substrate to induce a change in size of a structure; and
(S5) a step of controlling a shape of a growing three-dimensional nanostructure while transporting the lower substrate in three dimensions.

2. The method of claim 1, wherein the conductive mask is provided with a thin metal film coating layer on one or both sides of a film substrate or is in the form of a metal mesh.

3. The method of claim 2, wherein the thin metal film coating layer or the metal mesh comprises chromium (Cr), gold (Au), or a mixture thereof.

4. The method of claim 1, wherein the substrate comprises silicon (Si), indium tin oxide (ITO), or silicon carbide (SiC).

5. The method of claim 1, wherein the electric field intensity between the conductive mask and the substrate is 5 V/μm to 200 V/μm.

6. The method of claim 5, wherein the electric field intensity between the conductive mask and the substrate is 16.67 V/μm to 100 V/μm.

7. The method of claim 1, wherein an intensity of the electric field (Eₙₒₘ) generated in the step (S2) satisfies the following Equation 1:
$${E}_{n o m} = electrical potential of substrate ( V ) / moving distance of charged nanoparticles ( μm ) . \qquad [ Equation 1 ]$$

8. The method of claim 7, wherein the moving distance of the charged nanoparticles is a distance between the upper inlet of the reactor and the substrate.

9. A three-dimensional structure manufactured by the method according to claim 1, wherein the three-dimensional structure has a size that satisfies the following Equation 2:
$${W}_{D} = {W ( \frac{α {E}_{nom} d}{Δ V} )}^{\frac{1}{2}} ( \frac{2}{\sqrt{π}} ) \qquad [ Equation 2 ]$$
wherein W_{D} is a diameter (μm) of a stump of the three-dimensional structure,
W is a spacing (μm) between the holes provided in the conductive mask,
ΔV is an electric potential difference (V) between the conductive mask and the lower substrate,
d is a separation distance (μm) between the conductive mask and the lower substrate,
α is a constant, and
Eₙₒₘ is an intensity of an electric field (V/μm) generated by the electric potential difference between the conductive mask and the lower substrate.

10. The three-dimensional structure of claim 9, wherein the value of α in the Equation 2 is 5.

11. An apparatus for manufacturing a three-dimensional structure for use in the method according to claim 1, comprising:
a grounded reactor;
a lower substrate located within the grounded reactor;
a conductive mask disposed to be spaced apart above the lower substrate within the grounded reactor and provided with a plurality of holes;
an electric field applying means for generating electric fields of different sizes in the conductive mask and the lower substrate, respectively, to form an electrostatic lens around the hole of the mask;
a nanoparticle introducing means for introducing charged nanoparticles into an upper part of the conductive mask;
an electric field adjusting means for adjusting the sizes of the electric fields applied to the conductive mask and the lower substrate; and
a transporting means for transporting the lower substrate in three dimensions.

12. The apparatus of claim 11, wherein the conductive mask is provided with a thin metal film coating layer on one or both sides of a film substrate or is in the form of a metal mesh.

13. The apparatus of claim 12, wherein the thin metal film coating layer or the metal mesh comprises chromium (Cr), gold (Au), or a mixture thereof.

14. The apparatus of claim 11, wherein the substrate comprises silicon (Si), indium tin oxide (ITO), or silicon carbide (SiC).
